(19) United States
(12) Patent Application Publication
(10) Pub. No.: US 2025/0192062 A1
(43) Pub. Date: Jun. 12, 2025

(54) POWER MODULE

(71) Applicant: ZF Friedrichshafen AG, Friedrichshafen (DE)

(72) Inventors: Shaozhi Yuan, Shanghai (CN); Qing Xu, Shanghai (CN)

(73) Assignee: ZF Friedrichshafen AG, Friedrichshafen (DE)

(21) Appl. No.: 18/978,300

(22) Filed: Dec. 12, 2024

(30) Foreign Application Priority Data
Dec. 12, 2023 (CN) 202323400909.X

(51) Int. Cl. H01L 23/538; H01L 23/00; H01L 23/367; H01L 25/07

(52) U.S. Cl. CPC H01L 23/5386; H01L 24/48; H01L 25/072; H01L 23/3677; H01L 2224/48227

(57) ABSTRACT

A power module includes a power chip, and DC+, AC, and DC− busbars arranged substantially parallel to one another, where upper bridge power chips are linearly distributed between the DC+ and the AC busbars, and lower bridge power chips are linearly distributed between the AC and the DC− busbars, where each upper bridge power chip has a drain electrically connected to the DC+ busbar, a source electrically connected to the AC busbar, and a gate connected to a first gate busbar, where the first gate busbar is immediately adjacent to a connection between the source and AC busbar; and each lower bridge power chip has a drain electrically connected to the AC busbar, a source electrically connected to the DC− busbar, and a gate connected to a second gate busbar, where the second gate busbar is immediately adjacent to a connection between the source and the DC− busbar.

### CROSS-REFERENCE TO RELATED APPLICATION

This application claims priority to Chinese Patent Application No. 202323400909.X, filed on Dec. 12, 2023, the entirety of which is hereby fully incorporated by reference herein.

### TECHNICAL FIELD

The disclosure generally relates to the technical field of semiconductor devices, and in particular to a power module.

### BACKGROUND

Semiconductor devices are electronic devices that use the special electrical properties of semiconductor materials to achieve specific functions, and can be used for generating, controlling, receiving, transforming and amplifying signals and performing energy conversion. A power module is a power semiconductor device generally composed of a metal housing, a circuit board and elements. Various elements which may be diodes, transistors, capacitors, inductors or the like are arranged on the circuit board. In addition, depending on different specific applications, the power module may also include other components such as a control circuit and a protective circuit. The power modules of different types and uses may be somewhat different in structure.

With the development of technology, the performance of the power module is constantly improved and optimized. For example, the reliability of the power module is improved by selecting high-reliability elements, optimizing the structure of the power module, enhancing the production process control, etc.; the adaptability of the power module is improved by selecting multi-purpose elements, adding interfaces, etc.; and the power density of the power module may also be increased by using high thermal-conductivity materials, increasing the assembly density, etc., to reduce the size and the weight of the module and improve its power output capability. Optimizing the structure of the power module is an important means to improve the performance of the power module.

Common ways to optimize the structure of the power module in the prior art include: using chip elements instead of traditional in-line elements or selecting smaller-sized chips and devices; and using more integrated chips or devices or optimizing circuits to reduce the number of elements and wiring. The above-mentioned improving methods are mainly to optimize the structure from the aspects of reducing the number of the elements of the power module and reducing the sizes of the elements. In case of the same expenses, the performance and the reliability may be sacrificed to some extent to achieve the purpose of reducing the size of the power module. To guarantee the performance and the reliability of the power module, elements with better performance may be selected, which will inevitably increase the manufacturing cost.

### SUMMARY

A technical problem to be solved by the disclosure is to provide a power module which, by optimizing the structural layouts of each busbar and power chip, is higher in integration level while the performance of the power module is ensured, so as to reduce the size of the power module and reduce the manufacturing cost.

In order to solve the above technical problem, the disclosure provides a power module, including: a power chip, the power chip comprising upper bridge power chips and lower bridge power chips, and a DC+ busbar, an AC busbar and a DC-busbar being arranged substantially parallel to one another; wherein a plurality of upper bridge power chips are linearly distributed between the DC+ busbar and the AC busbar, and a plurality of lower bridge power chips are linearly distributed between the AC busbar and the DC− busbar, that is, the upper bride power chips and the lower bridge power chips are arranged in length directions of the busbars, where the upper bridge power chips and the lower bridge power chips are equal in number; each of the upper bridge power chips has a drain electrically connected to the DC+ busbar, a source electrically connected to the AC busbar and a gate connected to a first gate busbar; where the first gate busbar is immediately adjacent to a connection between the source and the AC busbar; and each of the lower bridge power chips has a drain electrically connected to the AC busbar, a source electrically connected to the DC− busbar and a gate connected to a second gate busbar; where the second gate busbar is immediately adjacent to a connection between the source and the DC− busbar.

Optionally, a plurality of drain pads are arranged on the DC+ busbar, a drain bonding wire of each of the upper bridge power chips being electrically connected to a corresponding drain pad; a plurality of source pads are arranged on a side of the AC busbar close to the upper bridge power chips, a source bonding wire of each of the upper bridge power chips being electrically connected to a corresponding source pad; a plurality of drain pads are arranged on a side of the AC busbar close to the lower bridge power chips, a drain bonding wire of each of the lower bridge power chips being electrically connected to a corresponding drain pad; and a plurality of source pads are arranged on the DC− busbar, a source bonding wire of each of the lower bridge power chips being electrically connected to a corresponding source pad.

Optionally, each of the source pads arranged on at least one of the AC busbar and the DC− busbar includes a plurality of welding blocks, the welding blocks of each of the source pads and the bonding wires led out from the source of a corresponding power chip are equal in number, and one of the bonding wires is electrically connected to each of the welding blocks.

Optionally, at least one of the first gate busbar and the second gate busbar includes one comb-shaped first sub-busbar and one comb-shaped second sub-busbar; all comb teeth of the first sub-busbar are positioned on the same side, and all comb teeth of the second sub-busbar are positioned on the same side; and the first sub-busbar and the second sub-busbar are arranged opposite to each other, and each of the source pads is positioned between two adjacent comb teeth of the first sub-busbar and also positioned between two adjacent comb teeth of the second sub-busbar.

Optionally, the comb teeth of the first sub-busbar are in interference fit with the comb teeth of the second sub-busbar.

Optionally, each comb tooth of at least one of the first sub-busbar and the second sub-busbar is provided with a gate pad, and a gate bonding wire of the power chip is electrically connected to the gate pad.

Optionally, the power module further includes an enclosure, the enclosure covering the power module and exposing an external conductive area of a conductive element of the power module.

Optionally, a heat dissipation structure is further provided on a back surface of the power module.

Optionally, an insulating resin layer is provided on the back surface of the power module, and the heat dissipation structure is arranged on a surface of the insulating resin layer.

Optionally, the heat dissipation structure is a finned heat dissipation structure.

Compared with the prior art, the disclosure has the following advantages. The DC+ busbar, the AC busbar and the DC− busbar are arranged substantially parallel to one another; each upper bridge power chip has a drain electrically connected to the DC+ busbar, a source electrically connected to the AC busbar and a gate connected to a first gate busbar, where the first gate busbar is immediately adjacent to a connection between the source and AC busbar; and each lower bridge power chip has the drain electrically connected to the AC busbar, the source electrically connected to the DC-busbar, and the gate connected to the second gate busbar, where the second gate busbar is immediately adjacent to a connection between the source and the DC-busbar, which in turn enables the power chip to be arranged compactly, reduces the distance between elements and ultimately reduces the size of the power module.

The accompanying drawings are included to provide a further understanding of the present application and are incorporated into and form a part of the present application, show embodiments of the present application, and serve to, together with the description, explain the principles of the present application.

### BRIEF DESCRIPTION OF THE DRAWINGS

FIG. 1 is a schematic diagram of an overall structure of a power module according to an embodiment of the disclosure;

FIG. 2 is a schematic structural diagram of the power module according to an embodiment of the disclosure, with a power chip removed;

FIG. 3 is a schematic structural diagram of a gate busbar according to an embodiment of the disclosure;

FIG. 4 is a schematic structural diagram of the power module according to an embodiment of the disclosure, with the gate busbar removed;

FIG. 5 is a schematic structural diagram of the structure shown in FIG. 2, with an enclosure removed;

FIG. 6 is a schematic diagram of the position of a gate pad according to an embodiment of the disclosure;

FIG. 7 is a side view of the structure shown in FIG. 6;

FIG. 8 is a schematic diagram of another fitting method of sub-busbars according to an embodiment of the disclosure;

FIG. 9 is a schematic diagram of a heat dissipation structure according to an embodiment of the disclosure; and

FIG. 10 is a schematic structural diagram of the structure shown in FIG. 9, with the enclosure removed.

### DETAILED DESCRIPTION

To describe technical solutions of embodiments of the present application more clearly, the accompanying drawings required for describing the embodiments will be briefly described below. Obviously, the accompanying drawings described below show merely some of the examples or embodiments of the present application, and those of ordinary skill in the art would also have applied the present application to other similar scenarios according to these accompanying drawings without involving any creative effort. Unless obvious from the language context or otherwise illustrated, the same reference numerals in the drawings represent the same structure or operation.

For ease of description, spatial relative terms such as “over . . . ”, “above . . . ”, “on upper surface of . . . ”, and “on . . . ” may be used here to describe a spatial position relationship between one device or feature and another device or feature as shown in the figures. It should be understood that the spatial relative terms are intended to encompass different orientations of the device in use or operation, in addition to the orientation of the device described in the figure. For example, if devices in the figure are inverted, the device described as “above” or “over” another device or structure will later be positioned as “below” or “under” another device or structure. Therefore, the exemplary term “above . . . ” may include both “above . . . ” and “below . . . ” orientations. The device may also be positioned in other different ways (rotated by 90 degrees or in other orientations), and the spatial relative descriptions used here are interpreted accordingly.

Furthermore, it should be noted that the use of terms such as “first” and “second” to define parts is merely for ease of facilitating differentiation of the corresponding parts. If not otherwise stated, the above terms have no special meanings and thus cannot be construed as limiting the scope of protection of the present application. Furthermore, although the terms used in the present application are selected from well-known common terms, some of the terms mentioned in the description of the present application may have been selected by the applicant according to his or her determination, and the detailed meaning thereof is described in the relevant section described herein. Furthermore, the present application must be understood, not simply by the actual terms used but also by the meanings encompassed by each term.

It should be understood that when a component is said to be “located on another component”, “connected to another component”, “coupled to another component”, or “in contact with another component”, it may be directly located on the other component, connected or coupled to the other component, or in contact with the other component, or there may be an intervening component. In contrast, when a component is said to be “directly located on another component”, “directly connected to another component”, “directly coupled to another component”, or “in direct contact with another component”, there is no intervening component. Similarly, when a first component is said to be “in electrical contact with” or “electrically coupled to” a second component, there is an electrical path between the first component and the second component that allows the flow of current. The electrical path can include a capacitor, coupled inductors, and/or other components that allow the flow of current, even without direct contact between conductive components.

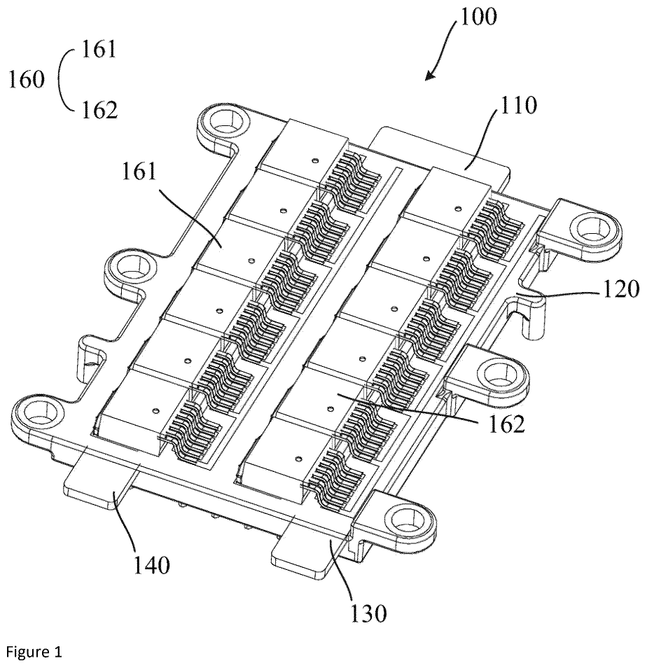

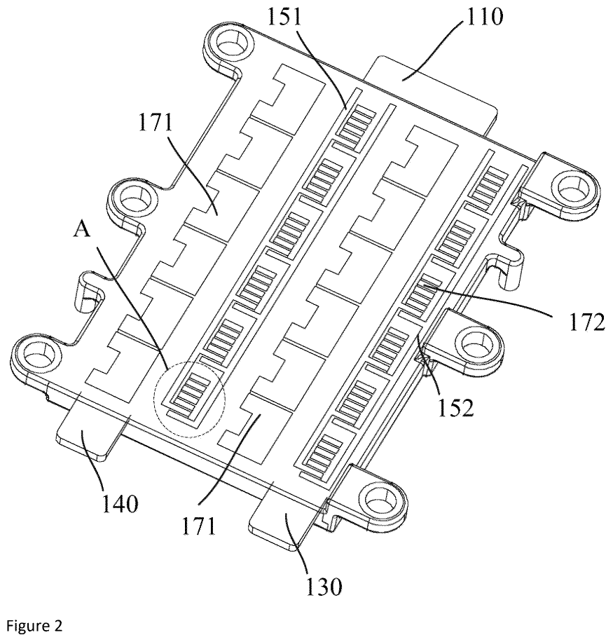

Referring to FIGS. 1 and 2, an embodiment provides a power module (power supply module) 100, mainly including:

a power chip 160 including upper bridge power chips 161 and lower bridge power chips 162, and a DC+ busbar 140, an AC busbar 110 and a DC− busbar 130 arranged substantially parallel to one another; where a plurality of upper bridge power chips 161 are linearly distributed between the DC+ busbar 140 and the AC busbar 110, and a plurality of lower bridge power chips 162 are linearly distributed between the AC busbar 110 and the DC− busbar 130, where the upper bridge power chips 161 and the lower bridge power chips 162 are equal in number; each upper bridge power chip 161 has a drain electrically connected to the DC+ busbar 140, a source electrically connected to the AC busbar 110, and a gate connected to the first gate busbar 151, where the first gate busbar 151 is immediately adjacent to a connection between the source and AC busbar 110; and each lower bridge power chip 162 has a drain electrically connected to the AC busbar 110, a source electrically connected to the DC-busbar 130, and a gate connected to a second gate busbar 152, where the second gate busbar 152 is immediately adjacent to a connection between the source and the DC-busbar 130.

In this embodiment, the DC+ busbar 140, the AC busbar 110 and the DC-busbar 130 are arranged substantially parallel to one another, and the upper bridge power chips 161 are linearly distributed (i.e., in a line) parallel to the DC+ busbar 140, etc., and similarly, the lower bridge power chips 162 are linearly distributed parallel to the DC+ busbar 140, etc. The upper bridge power chips 161 and the lower bridge power chips 162 are arranged in length directions of the busbars. This arrangement of elements makes the positions of the elements more regular and the structure more compact, and also simplifies the AC/DC connection method. Also, the first gate busbar 151 is immediately adjacent to the connection between the source and AC busbar 110, and the second gate busbar 152 is immediately adjacent to the connection between the source and DC− busbar 130, i.e., the gate busbars do not additionally take up more space, which further reduces the size of the power module 100 and makes a package size more integrated.

In an example, a plurality of drain pads 171 are arranged on the DC+ busbar 140, a drain bonding wire of each upper bridge power chip 161 being electrically connected to a corresponding drain pad 171; a plurality of source pads 172 are arranged on a side of the AC busbar 110 close to the upper bridge power chips 161, a source bonding wire of each upper bridge power chip 161 being electrically connected to a corresponding source pad 172, and a plurality of drain pads 171 are arranged on a side of the AC busbar 110 close to the lower bridge power chips 162, a drain bonding wire of each lower bridge power chip 162 being electrically connected to a corresponding drain pad 171; and a plurality of source pads 172 are arranged on the DC− busbar 130, a source bonding wire of each lower bridge power chip 162 being electrically connected to a corresponding source pad 172.

Bonding wires of a source and a drain of the power chip 160 are connected by pads to achieve more stable electrical connections and higher mechanical strength, such that the performance stability and reliability of the power module 100 in complex environment can be guaranteed. Using the pads as electrical connections, which has a low contact resistance, can provide more efficient power transmission and thus is conducive to improving the efficiency of the power module 100.

In an example, each of the source pads 172 arranged on at least one of the AC busbar 110 and the DC− busbar 130 includes a plurality of welding blocks, the welding blocks of each source pad 172 and the bonding wires led out from the source of a corresponding power chip 160 are equal in number, and one of the bonding wires is electrically connected to each of the welding blocks.

Referring to FIG. 2, A represents one source pad 172, here the source pad is composed of 5 small welding blocks, and correspondingly, here the power chip 160 has 5 bonding wires led out from the source, and each bonding wire is electrically connected to one welding block. The plurality of welding blocks can better dissipate heat from a welding point and avoid welding failure or damage due to overheating of an individual welding point, thus making the welding more robust and more reliable.

In an example, at least one of the first gate busbar 151 and the second gate busbar 152 includes one comb-shaped first sub-busbar 1501 and one comb-shaped second sub-busbar 1502. All comb teeth 1503 of the first sub-busbar 1501 are positioned on the same side, and all comb teeth 1503 of the second sub-busbar 1502 are positioned on the same side. The first sub-busbar 1501 and the second sub-busbar 1502 are arranged opposite to each other. Each source pad 172 is positioned between two adjacent comb teeth 1503 of the first sub-busbar 1501 and also positioned between two adjacent comb teeth 1503 of the second sub-busbar 1502.

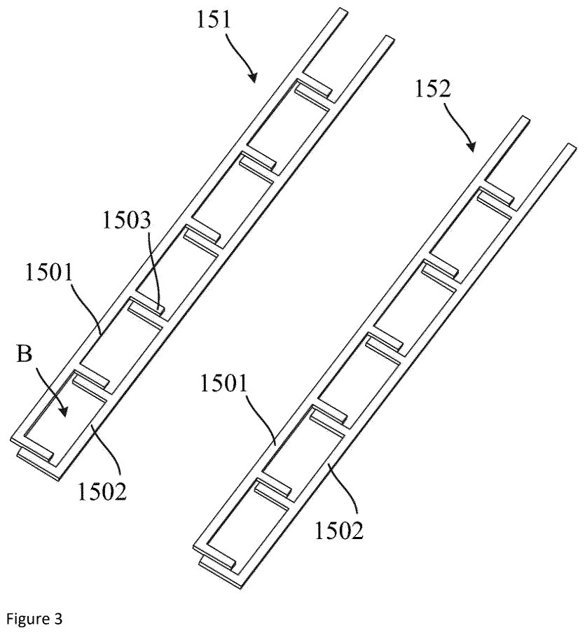

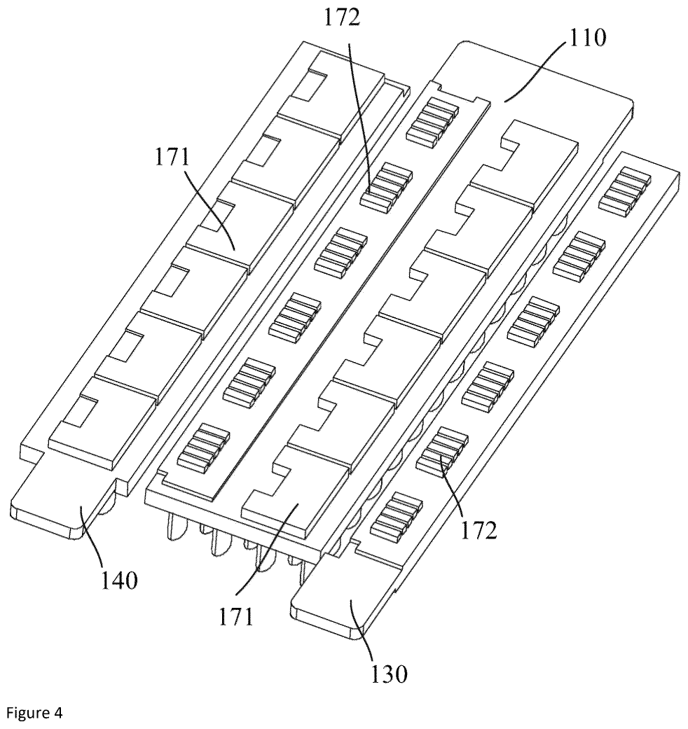

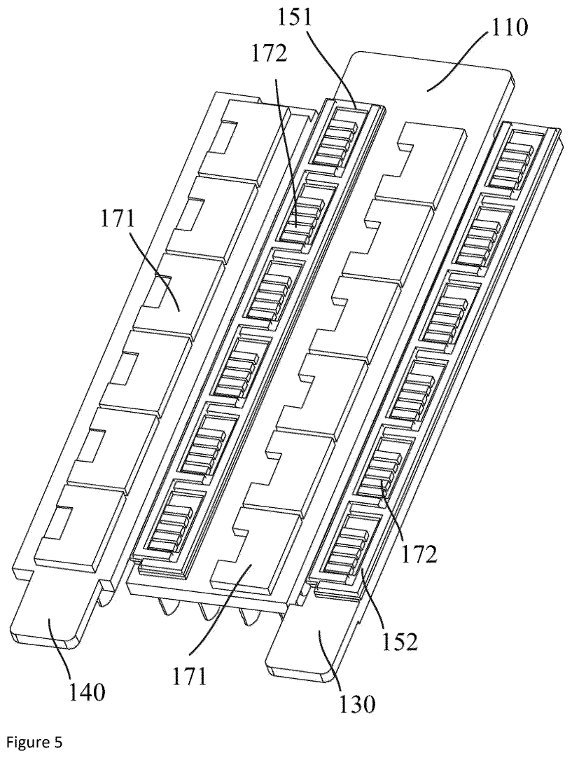

Referring to FIG. 3, in an example of the first gate busbar 151, the first sub-busbar 1501 with a plurality of comb teeth 1503 distributed thereon is arranged on the left, every two adjacent comb teeth 1503 may be equidistantly or non-equidistantly spaced, and each comb tooth 1503 is oriented to the right. The second sub-busbar 1502 with a plurality of comb teeth 1503 distributed thereon is arranged on the right side of the first gate busbar 151, every two adjacent comb teeth 1503 may be equidistantly or non-equidistantly spaced, and each comb tooth 1503 is oriented to the left. The two sub-busbars are arranged opposite to each other to form a plurality of accommodating spaces as shown at B in the figure. Referring to FIGS. 4 and 5, a source pad 172 may be accommodated at B in the figure. Therefore, the space occupied by the first gate busbar 151 can be reduced, which reduces the size of the power module 100.

Further, if the source pads 172 are small, the first sub-busbar 1501 and the second sub-busbar 1502 may be somewhat misaligned such that the first sub-busbar 1501 and the second sub-busbar 1502 are closer to each other, and the formed accommodating spaces may accommodate or adapt to the smaller source pads 172. Reference may be made to the structure of the first gate busbar 151 for the details of the second gate busbar 152, which will not be repeated herein.

In an example, each comb tooth 1503 of at least one of the first sub-busbar 1501 and the second sub-busbar 1502 is provided with a gate pad 173, and gate bonding wires of the power chip 160 are electrically connected to the gate pads 173, such that the electrical connection is more stable and the mechanical strength is higher, for which reference may be made to relevant descriptions of the performance when the aforementioned pads use welding blocks and which will not be repeated herein.

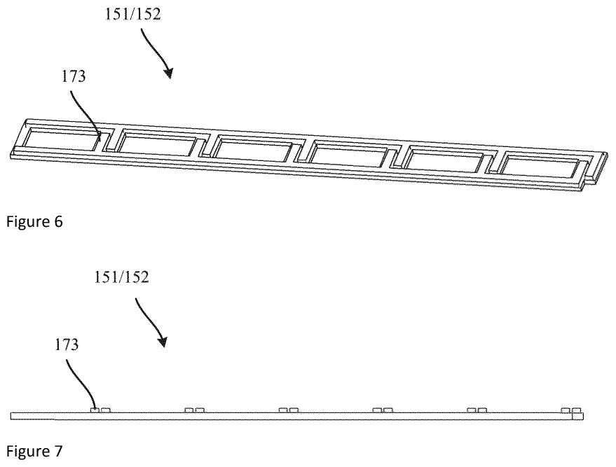

Referring to FIGS. 6 and 7, in this embodiment, pre-injection molding may be performed on the first gate busbar 151 and the second gate busbar 152 to cover areas to be insulated, with only areas that need to be metallically connected exposed.

In an example, the power module 100 further includes an enclosure 120, the enclosure 120 covering the power module 100 and exposing an external conductive area of a conductive element of the power module 100. It can be understood that covering the power module 100 with the enclosure 120 means that the enclosure 120 encloses other elements of the power module 100 since the enclosure 120 is also a part of the power module 100. In this embodiment, the enclosure 120 may be formed by injection molding. By way of example, the first gate busbar 151 and the second gate busbar 152 that are pre-injection-molded may be assembled to a busbar main body (mainly including a DC+ busbar, a DC− busbar and an AC busbar), the assembled busbar main body is injection-molded again to cover areas to be insulated and expose only areas to be electrically connected. The areas to be electrically connected are areas on the busbar main body that are connected to the source, the drain and the gate of the power chip 160.

In this embodiment, most circuit connections are embedded into a PCB, such that the power module 100 has lower stray inductance. In addition, since all the busbars and the power chip 160 are also embedded into the PCB, the circuit connections between the busbars and the power chip 160 are shortened, which can also reduce the inductance.

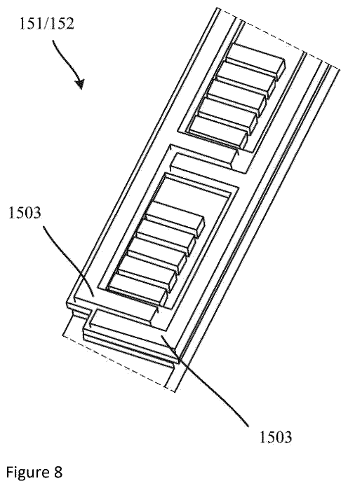

In an example, referring to FIG. 8, the comb teeth 1503 of the first sub-busbar 1501 are in interference fit with the comb teeth 1503 of the second sub-busbar 1502 to limit the movements of the first sub-busbar 1501 and the second sub-busbar 1502 in a planar direction, such that the structure of the gate busbar is more stable.

In an example, a heat dissipation structure 180 is further provided on a back surface of the power module 100. Further, an insulating resin layer (not shown in the figure) is provided on the back surface of the power module 100, and the heat dissipation structure 180 is arranged on a surface of the insulating resin layer.

The heat dissipation structure 180 is an important component which may effectively dissipate heat generated by the power module 100 to ensure normal operations of the power module 100. In this embodiment, the insulating resin layer is provided on the back surface of the power module 100, and the insulating resin layer is not an insulating layer inside the PCB, such that the heat dissipation performance of the power module 100 can be improved.

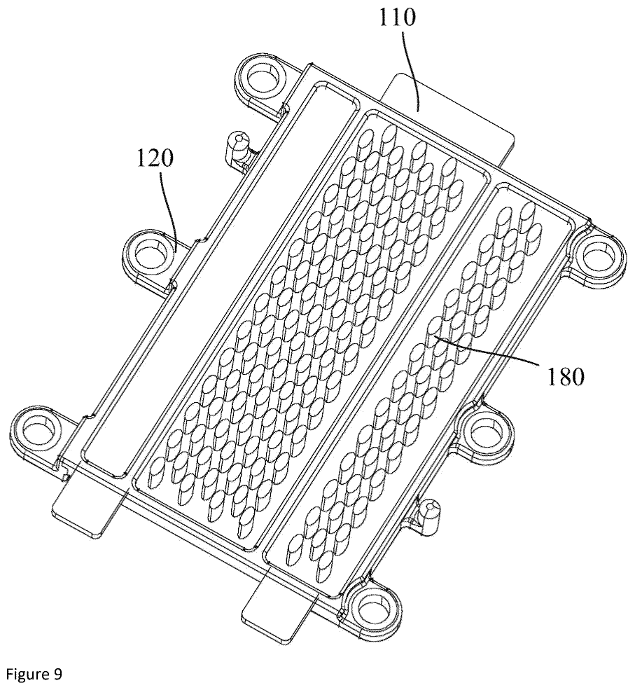

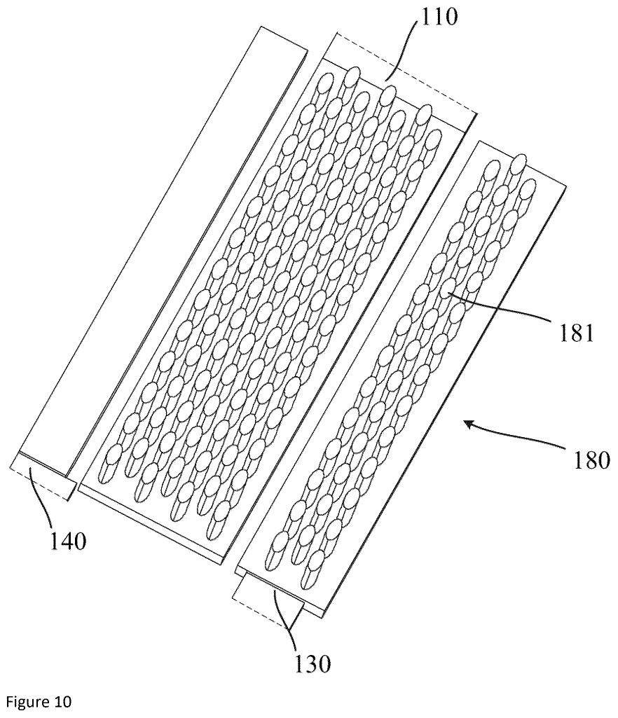

In an example, referring to FIGS. 9 and 10, the heat dissipation structure 180 is a finned heat dissipation structure. The finned heat dissipation structure is the heat dissipation structure 180 with fins 181, and the fins 181 are core components of the finned heat dissipation structure and are generally made of a metallic material, such as aluminum alloy and copper, which significantly improves the heat dissipation performance. The fins 181 may be in the form of flat sheets, wavy sheets or corrugated sheets, etc., which will not be listed herein, and mainly function to increase the surface area of the heat dissipation structure 180 so as to improve the heat dissipation effect.

In the power module 100 provided in this embodiment, the DC+ busbar 140, the AC busbar 110 and the DC− busbar 130 are arranged substantially parallel to one another. Each upper bridge power chip 161 has the drain electrically connected to the DC+ busbar 140, the source electrically connected to the AC busbar 110 and the gate connected to the first gate busbar 151, where the first gate busbar 151 is immediately adjacent to the connection between the source and the AC busbar 110. Each lower bridge power chip 162 has the drain electrically connected to the AC busbar 110, the source electrically connected to the DC− busbar 130 and the gate connected to the second gate busbar 152, where the second gate busbar 152 is immediately adjacent to the connection between the source and the DC− busbar 130. Therefore, the power chip 160 can be arranged compactly, a distance between elements is reduced, and the size of the power module 100 can be ultimately reduced.

The basic concepts have been described above. Obviously, for those skilled in the art, the above disclosure of the disclosure is merely used as an example and does not constitute a limitation on the present application. Although not explicitly stated herein, various modifications, improvements and amendments may be made to the present application by those skilled in the art. Such modifications, improvements and amendments are suggested in the present application, and therefore, such modifications, improvements and amendments still fall within the spirit and scope of the exemplary embodiments of the present application.

Similarly, it should be noted that to simplify the expressions in the disclosure of the present application to assist in the understanding of one or more embodiments of the disclosure, a plurality of features may sometimes be incorporated into an embodiment and accompanying drawing, or a description thereof in the foregoing description of the embodiments of the present application. However, such a method in the disclosure does not mean that the subject of the present application requires more features than those mentioned in the claims. In fact, the features of the embodiments are less than all the features of a single embodiment disclosed above.

While the present application has been described with reference to the specific embodiments at hand, those of ordinary skill in the art would realize that the above embodiments are merely used to illustrate the present application, and various equivalent changes or substitutions can also be made without departing from the spirit of the present application. Therefore, any change and variation made to the above embodiments within the substantial spirit and scope of the present application shall fall within the scope of the claims of present application.

### REFERENCE NUMBERS

100—power module
110—AC busbar
120—enclosure
130—DC− busbar
140—DC+ busbar
151—first gate busbar
152—second gate busbar
1501—first sub-busbar
1502—second sub-busbar
1503—comb tooth
160—power chip
161—upper bridge power chip
162—lower bridge power chip
171—drain pad
172—source pad
173—gate pad
180—heat dissipation structure
181—fin

1. A power module, comprising:
a power chip comprising upper bridge power chips and lower bridge power chips, and a DC+, an AC busbar, and a DC− busbar being arranged substantially parallel to one another,
wherein a plurality of the upper bridge power chips are linearly distributed between the DC+ busbar and the AC busbar, and a plurality of the lower bridge power chips are linearly distributed between the AC busbar and the DC− busbar, wherein the upper bridge power chips and the lower bridge power chips are equal in number,
wherein each of the upper bridge power chips has a drain electrically connected to the DC+ busbar, a source electrically connected to the AC busbar, and a gate connected to a first gate busbar, wherein the first gate busbar is immediately adjacent to a connection between the source and the AC busbar, and
wherein each of the lower bridge power chips has a drain electrically connected to the AC busbar, a source electrically connected to the DC− busbar, and a gate connected to a second gate busbar, wherein the second gate busbar is immediately adjacent to a connection between the source and the DC− busbar.

2. The power module of claim 1,
wherein a plurality of DC+ busbar drain pads are arranged on the DC+ busbar, a drain bonding wire of each of the upper bridge power chips being electrically connected to a corresponding DC+ busbar drain pad,
wherein a plurality of AC busbar source pads are arranged on a side of the AC busbar close to the upper bridge power chips, a source bonding wire of each of the upper bridge power chips being electrically connected to a corresponding AC busbar source pad,
wherein a plurality of AC busbar drain pads are arranged on a side of the AC busbar close to the lower bridge power chips, a drain bonding wire of each of the lower bridge power chips being electrically connected to a corresponding AC busbar drain pad, and
wherein a plurality of DC− busbar source pads are arranged on the DC− busbar, a source bonding wire of each of the lower bridge power chips being electrically connected to a corresponding DC− busbar source pad.

3. The power module of claim 2,
wherein each of the AC busbar source pads or the DC− busbar source pads arranged on at least one of the AC busbar and the DC− busbar comprises a plurality of welding blocks, wherein the welding blocks of each of the source pads and the bonding wires led out from the source of a corresponding power chip are equal in number, and one of the bonding wires is electrically connected to each of the welding blocks.

4. The power module of claim 3,
wherein at least one of the first gate busbar and the second gate busbar comprises one comb-shaped first sub-busbar and one comb-shaped second sub-busbar, and
wherein all comb teeth of the first sub-busbar are positioned on a same side, and all comb teeth of the second sub-busbar are positioned on a same side, and wherein the first sub-busbar and the second sub-busbar are arranged opposite to each other, and each of the source pads is positioned between two adjacent comb teeth of the first sub-busbar and also positioned between two adjacent comb teeth of the second sub-busbar.

5. The power module of claim 4,
wherein the comb teeth of the first sub-busbar are in interference fit with the comb teeth of the second sub-busbar.

6. The power module of claim 4,
wherein each comb tooth of at least one of the first sub-busbar and the second sub-busbar is provided with a gate pad, and a gate bonding wire of the power chip is electrically connected to the gate pad.

7. The power module of claim 1, comprising:
an enclosure covering the power module and exposing an external conductive area of a conductive element of the power module.

8. The power module of claim 7, comprising:
a heat dissipation structure provided on a back surface of the power module.

9. The power module of claim 8, comprising:
an insulating resin layer provided on the back surface of the power module, wherein the heat dissipation structure is arranged on a surface of the insulating resin layer.

10. The power module of claim 8, wherein the heat dissipation structure is a finned heat dissipation structure.
